(19) United States
(12) Patent Application Publication
(10) Pub. No.: US 2010/0182611 A1
(43) Pub. Date: Jul. 22, 2010

(54) DISPLACEMENT MEASURING APPARATUS AND DISPLACEMENT MEASURING METHOD

(75) Inventor: Yuji Sudoh, Hadano-shi (JP)

Correspondence Address: ROSSI, KIMMS & McDOWELL LLP., 20609 Gordon Park Square, Suite 150, Ashburn, VA, 20147, US

(73) Assignee: CANON KABUSHIKI KAISHA, Tokyo (JP)

(21) Appl. No.: 12/690,452

(22) Filed: Jan. 20, 2010

(30) Foreign Application Priority Data
Jan. 20, 2009 (JP) 2009-009538

(51) Int. Cl. G01B 11/14; G01B 7/14; G01B 9/02; G01R 27/26

(52) U.S. Cl. 356/498; 324/662

(57) ABSTRACT

A displacement measuring apparatus 100 which measures a displacement of an object to be measured 1 comprises a ranging sensor 5 configured to detect a first origin position based on a distance to a base 2, a ranging sensor 6 configured to detect a second origin position based on a distance to the object to be measured 1, a stage 4 mounting the ranging sensors 5 and 6 and configured to move in a ranging direction of the ranging sensors 5 and 6, and a controller 7 configured to measure a displacement of the object to be measured 1 with respect to the base 2 using the first and second origin positions detected while moving the ranging sensors 5 and 6.

### BACKGROUND OF THE INVENTION

1. Field of the Invention

The present invention relates to a displacement measuring apparatus and a displacement measuring method which measure a displacement of an object to be measured.

2. Description of the Related Art

In a precision industrial product, highly accurate positioning of parts with respect to a reference member that is a position reference is required. In addition, a minute position displacement may be generated for parts fixed on the reference member due to disturbance such as vibration, shock, or thermal shock. Therefore, in a common precision industrial product, a ranging sensor is used for positioning the parts or detecting a position displacement of the parts.

When a displacement of a desired position (an object to be measured) is measured considering a certain position as a reference, for example there is a method of monitoring displacement information of the object to be measured using a ranging sensor which is fixed on a reference member that is a position reference. In this method, however, the measurement accuracy is deteriorated in a long-time measurement due to a drift of a sensor output because the ranging sensor has to be always activated. Further, in a real industrial product, it is often the case that the ranging sensor can not be always equipped with the reference member due to limitations of the apparatus structure.

Therefore, a method of measuring the reference member using the ranging sensor set on an arbitrary position and then moving the ranging sensor up to a measurement position of the object to be measured to measure the position of the object to be measured has been used. According to the method, relative displacement information can be obtained based on a moving distance and a measurement result of the ranging sensor. FIGS. 7A and 7B are schematic diagrams of a displacement measuring apparatus which measures a displacement of an object to be measured 107 using the method.

As shown in FIG. 7A, a Z stage 110 is set at a position distant from both a reference member 108 and the object to be measured 107. A non-contact type ranging sensor 112 is mounted on a moving table 111 of the Z stage 110. After the ranging sensor 112 measures a distance to the reference member 108, the moving table 111 is driven along a guide and the ranging sensor 112 performs a ranging again at a measurement position of the object to be measured 107 (FIG. 7B). Then, a relative distance of the object to be measured 107 with respect to the reference member 108 is measured based on a difference between a distance to the object to be measured 107 and a distance to the already obtained reference member 108.

In the above conventional method described referring to FIGS. 7A and 7B, however, a driving accuracy or a straight-line stability of the stage which moves the ranging sensor influences on the measurement result. Therefore, when two points which are especially distant from each other are measured, the measurement accuracy is deteriorated.

### BRIEF SUMMARY OF THE INVENTION

The present invention provides highly accurate displacement measuring apparatus and displacement measuring method.

A displacement measuring apparatus as one aspect of the present invention is a displacement measuring apparatus which measures a displacement of an object to be measured. The displacement measuring apparatus comprises a first detector configured to detect a first origin position based on a distance to a reference member, a second detector configured to detect a second origin position based on a distance to the object to be measured, a moving portion mounting the first and second detectors and configured to move in a ranging direction of the first and second detectors, and a measuring portion configured to measure a displacement of the object to be measured with respect to the reference member using the first and second origin positions detected while moving the first and second detectors.

A displacement measuring apparatus as another aspect of the present invention is a displacement measuring apparatus which measures a displacement of an object to be measured in a plurality of directions. The displacement measuring apparatus comprises a plurality of displacement detecting apparatuses arranged around the object to be measured, and a measuring portion configured to measure the displacement of the object to be measured with respect to a reference member based on an output of the plurality of displacement detecting apparatuses. Each of the plurality of displacement measuring apparatuses comprises a first detector configured to detect a first origin position based on a distance to a reference member, a second detector configured to detect a second origin position based on a distance to the object to be measured, and a moving portion mounting the first and second detectors and configured to move in a ranging direction of the first and second detectors. The measuring portion is configured to measure a displacement of the object to be measured with respect to the reference member using the first and second origin positions detected while moving the first and second detectors.

A displacement measuring method as another aspect of the present invention is a displacement measuring method of measuring a displacement of an object to be measured. The displacement measuring method comprising the steps of moving a first detector in a ranging direction of the first detector, detecting a first origin position by the first detector based on a distance to a reference member, moving a second detector in a ranging direction of the second detector, detecting a second origin position by the second detector based on a distance to the object to be measured, and measuring a displacement of the object to be measured with respect to the reference member based on a displacement of a difference between an output value of the second detector when the first detector detects the first origin position and an output value of the second detector when the second detector detects the second origin position.

Further features and aspects of the present invention will become apparent from the following description of exemplary embodiments with reference to the attached drawings.

### BRIEF DESCRIPTION OF THE DRAWINGS

FIGS. 1A and 1B are schematic configuration diagrams of a displacement measuring apparatus in Embodiment 1.

FIG. 2 is a block diagram showing a measurement flow in a displacement measuring apparatus of Embodiment 1.

FIG. 3 is a schematic configuration diagram of a displacement measuring apparatus which performs a preliminary measurement for measuring an absolute distance between a base and an object to be measured in Embodiment 1.

FIG. 4 is a block diagram showing a flow of a preliminary measurement in Embodiment 1.

FIGS. 5A and 5B are schematic configuration diagrams of a displacement measuring apparatus in Embodiment 2.

FIGS. 6A and 6B are schematic configuration diagrams of a displacement measuring apparatus in Embodiment 3.

FIGS. 7A and 7B are schematic configuration diagrams of a conventional displacement measuring apparatus.

### DETAILED DESCRIPTION OF THE PREFERRED EMBODIMENTS

Exemplary embodiments of the present invention will be described below with reference to the accompanied drawings. In each of the drawings, the same elements will be denoted by the same reference numerals and the duplicate descriptions thereof will be omitted.

### Embodiment 1

First, a displacement measuring apparatus in

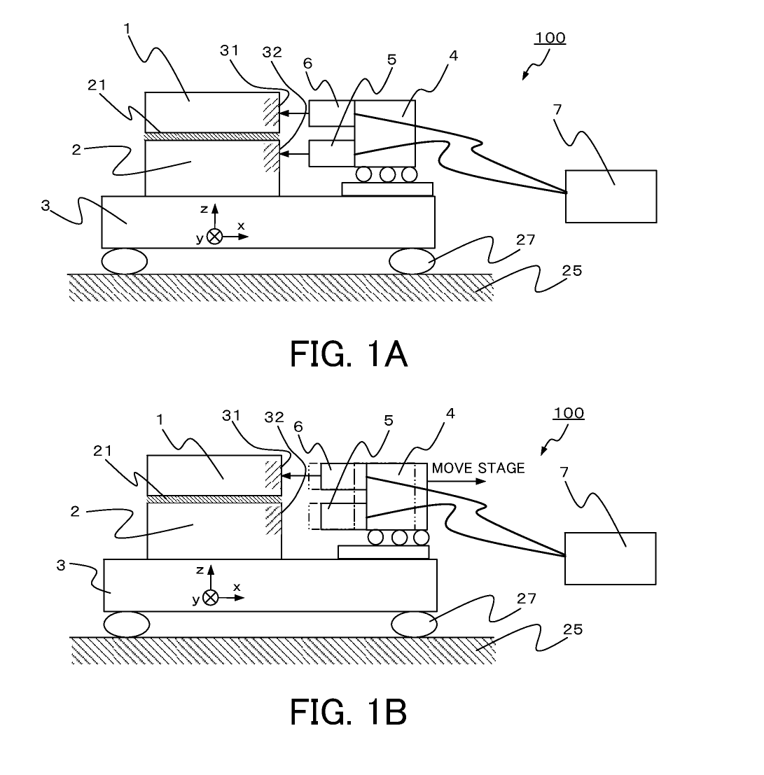

Embodiment 1 of the present invention will be described. FIGS. 1A and 1B are schematic configuration diagrams of a displacement measuring apparatus 100 in the present embodiment. The displacement measuring apparatus 100 is a measuring apparatus which measures a displacement of an object to be measured with respect to a reference member. FIG. 1A shows a state where origin detection is performed by using a ranging sensor 5, and FIG. 1B shows a state where the origin detection is performed by using a ranging sensor 6.

In FIGS. 1A and 1B, reference numeral 1 denotes an object to be measured. The object to be measured 1 is mounted on a base 2 and is attached to the base 2 via adhesives 21. The base 2 is a reference member that is a positioning reference of the object to be measured 1. The base 2 is arranged on a platen 3. In the present embodiment, the base 2 is configured to be detachable from the platen 3. Reference numeral 4 denotes a stage (a moving portion) arranged on the platen 3. The stage 4 mounts non-contact type ranging sensors 5 and 6 (first and second detectors) in order to measure a distance between the object to be measured 1 and the base 2. The ranging sensor 5 as a first detector detects a first origin position based on a distance to the base 2. The ranging sensor 6 as a second detector detects a second origin position based on a distance to the object to be measured 1. The stage 4 is also, similarly to the base 2, configured to be detachable from the platen 3. The platen 3 is placed on a setting floor 25 via an air mount 27.

In the present embodiment, the ranging sensors 5 and 6 are, for example as disclosed in Japanese Patent Laid-open No. 2007-33317, interferometers capable of measuring absolute position information of an object to be measured, which set a position where a phase difference of interference signals of two light beams having different wavelengths from each other is zero as an origin position. The present embodiment is not limited to this, but other ranging sensors can also be used. For example, as ranging sensors 5 and 6, capacitance sensors which perform a ranging depending on changes of capacitance between the object to be measured 1 and the ranging sensors 5 and 6 can be used.

Reference numeral 7 denotes a controller (a measuring portion) of the ranging sensors 5 and 6. The controller 7 measures a displacement of the object to be measured 1 with respect to the base 2 using the first and second origin positions. In this case, the first and second origin positions are detected while the ranging sensors 5 and 6 are moved. The controller 7 includes a light source of the ranging sensors 5 and 6 and a display function of a sensor output value, and is coupled to the ranging sensors 5 and 6 using an electric cable and an optical fiber.

Mirror finishing is performed for measurement points 31 and 32 of the object to be measured 1 and the base 2 in order to reflect the light beams projected from the ranging sensors 5 and 6. Referring to FIG. 1B, the stage 4 is configured to be movable in a ranging direction of the ranging sensors 5 and 6 (an x direction in FIGS. 1A and 1B) by a driver (not shown). As described below, a certain angle displacement may be generated between the ranging direction and a stage driving direction (an x direction). In this case, the driving direction of the stage 4 is strictly different from the ranging direction, but is acceptable if it is substantially the same as the ranging direction. The present embodiment is not limited to the above configuration, but is acceptable if it is configured to change a relative distance between the object to be measured 1 and the base 2 and the ranging sensors 5 and 6. Therefore, for example, the base 2 can also be provided on a stage as a moving portion to be configured to move the object to be measured 1 and the base 2 using the stage.

The object to be measured 1 attached onto the base 2 may be relatively displaced with respect to the base 2 because of hardening contraction, time degradation, or the like of the adhesives 21. Therefore, the displacement measuring apparatus 100 of the present embodiment is configured to monitor the displacement of the object to be measured 1 from the state immediately after the object to be measured 1 is attached to the base 2 at predetermined intervals.

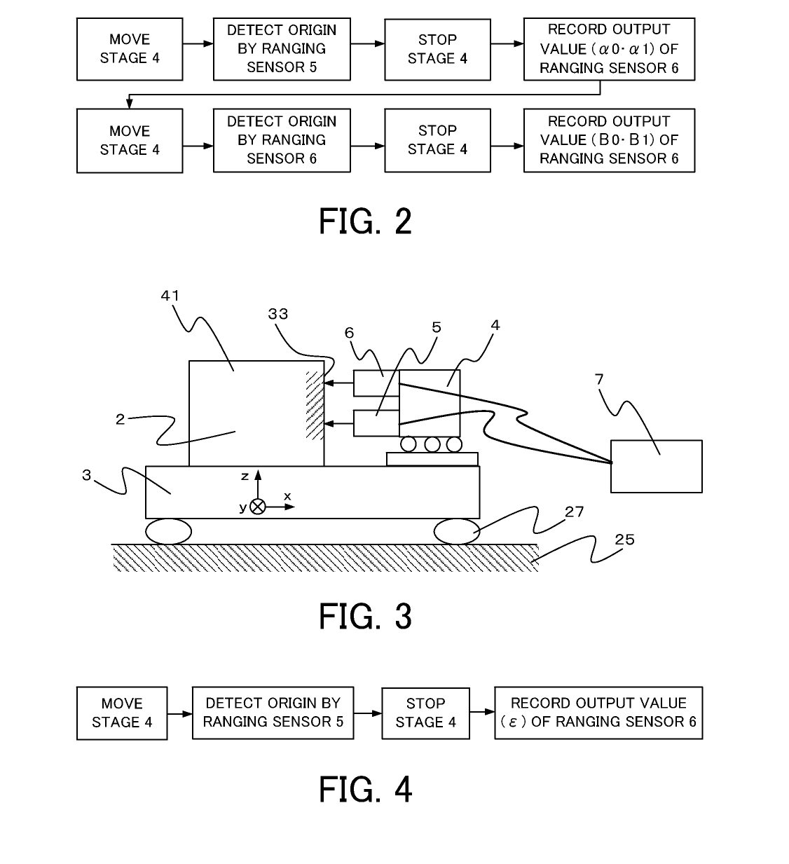

Next, a displacement measuring method which is performed by the displacement measuring apparatus 100 in the present embodiment will be described. FIG. 2 is a block diagram showing a measurement flow in the displacement measuring apparatus of the present embodiment.

First, in the displacement measuring method of the present embodiment, a driver (not shown) of the displacement measuring apparatus 100 moves the ranging sensor 5 in the ranging direction of the ranging sensor 5 (the x-axis direction in FIGS. 1A and 1B). In this case, referring to FIG. 1A, the driver moves the stage 4 up to the position (the first origin position of the ranging sensor 5) where a phase difference of interference signals detected by the ranging sensors 5 is zero. The ranging sensor 5 detects the first origin position based on a distance to the base 2. In the embodiment, an output value of the ranging sensor 6 when the ranging sensor 5 is located at the first origin position is defined as α0. The output value α0 is stored in the controller 7.

Next, the driver moves the ranging sensor 6 in the ranging direction of the ranging sensor 6 (the x-axis direction in FIGS. 1A and 1B). In this case, referring to FIG. 1B, the driver moves the stage 4 up to a position where a phase difference of interference signals detected by the ranging sensor 6 is zero (the second origin position of the ranging sensor 6). The ranging sensor 6 detects the second origin position based on a distance to the object to be measured 1. In the embodiment, an output value of the ranging sensor 6 when the ranging sensor 6 is located at the second origin position is defined as β0. The output value β0 is stored in the controller 7. Each processing required for obtaining the above output values α0 and β0 is performed immediately after the object to be measured 1 is attached to the base 2 (a default position).

In the present embodiment, the output values α0 and β0 may also be obtained in the order opposite to the above case. In this case, after the ranging sensor 6 obtains the output value β0 of the ranging sensor 6 when the ranging sensor 6 is located at the origin position, the ranging sensor 5 obtains the output value α0 of the ranging sensor 6 when the ranging sensor 5 is located at the origin position.

Next, after a predetermined time has passed after the output values α0 and β0 was obtained, the stage 4 (the ranging sensors 5 and 6) is moved similarly to the above procedure. In this case, output values of the ranging sensor 6 at the first and second origin positions are defined as α1 and β1, respectively. The output values α1 and β1 are also stored in the controller 7.

In the displacement measuring apparatus 100 of the present embodiment, the output values α0 and α1, and the output values β0 and β1 are different from each other due to a position error in setting the base 2 or the stage 4 on the platen 3 or application of power to the ranging sensor 5 again. For example, even when the ranging sensor 6 detects the same origin position (the second origin position), the output values (β0, β1) of the ranging sensor 6 are different before and after turning on/off of power to the ranging sensor 6. Thus, the output value of the ranging sensor 6 is different for each measurement. However, if a relative displacement (distance) between the object to be measured 1 and the base 2 is invariant, the differences (β0−α0) and (β1−α1) of the output values of the ranging sensor 6 are equal to each other.

On the other hand, when the distance between the object to be measured 1 and the base 2 is relatively displaced, a displacement δ of the object to be measured 1 with respect to the base 2 after a predetermined time has passed is represented by the following expression (1).

δ=(β0−α0)−(β1−α1) (1)

Thus, the controller 7 of the displacement measuring apparatus 100 calculates the displacement of the difference between the output value of the ranging sensor 6 when the ranging sensor 5 detects the first origin position and the output value of the ranging sensor 6 when the ranging sensor 6 detects the second origin position. The controller 7 measures the displacement of the object to be measured 1 with respect to the base 2 based on the calculated displacement. According to the displacement measuring apparatus 100 of the present embodiment, a relative displacement between two points can be stably measured with high accuracy because the stage with the two ranging sensors is configured to be movable in the ranging direction.

In the present embodiment, the case where the base 2 as a reference member and the object to be measured 1 are bonded with the adhesives 21 and a relative displacement between them with the passage of time is measured in a state where the object to be measured 1 is stably placed has been described. In the present embodiment, however, the object to be measured 1 and the ranging sensors 5 and 6 are detachable from the platen 3. Therefore, for example, it can also be used for verifying whether or not the object to be measured 1 has been displaced with respect to the base 2 by the influence of vibration, an external force, or the like in an environment where the object to be measured 1 is not placed on the platen 3.

Further, in the present embodiment, a method of measuring a displacement, with the passage of time, of the object to be measured which is fixed with respect to the base that is a positioning reference has been described. The present embodiment is not limited to this, but for example absolute position information of the object to be measured and the base can also be obtained.

FIG. 3 is a schematic configuration diagram of the displacement measuring apparatus when a preliminary measurement is performed for an absolute distance measurement of the base and the object to be measured. FIG. 4 is a block diagram showing a flow of the preliminary measurement. As shown in FIG. 3, a standard 41 by which the ranging sensors 5 and 6 are able to measure an identical plane is previously measured. Mirror finishing is performed for a measurement point 33 of the standard 41. The position of the standard 41 is measured by a flow shown in FIG. 4. First, the stage 4 is moved using a driver (not shown). When the origin is detected by the ranging sensor 5, the driver stops moving the stage 4 and an output c of the ranging sensor 6 at this time is stored in the controller 7. Subsequently, the measurement described referring to FIG. 2 is performed to obtain the calculated values (α0−ε) and (α1−ε) as relative distances between the object to be measured 1 and the base 2. Thus, according to the present embodiment, absolute distances of both the object to be measured 1 and the base 2 can be measured.

### Embodiment 2

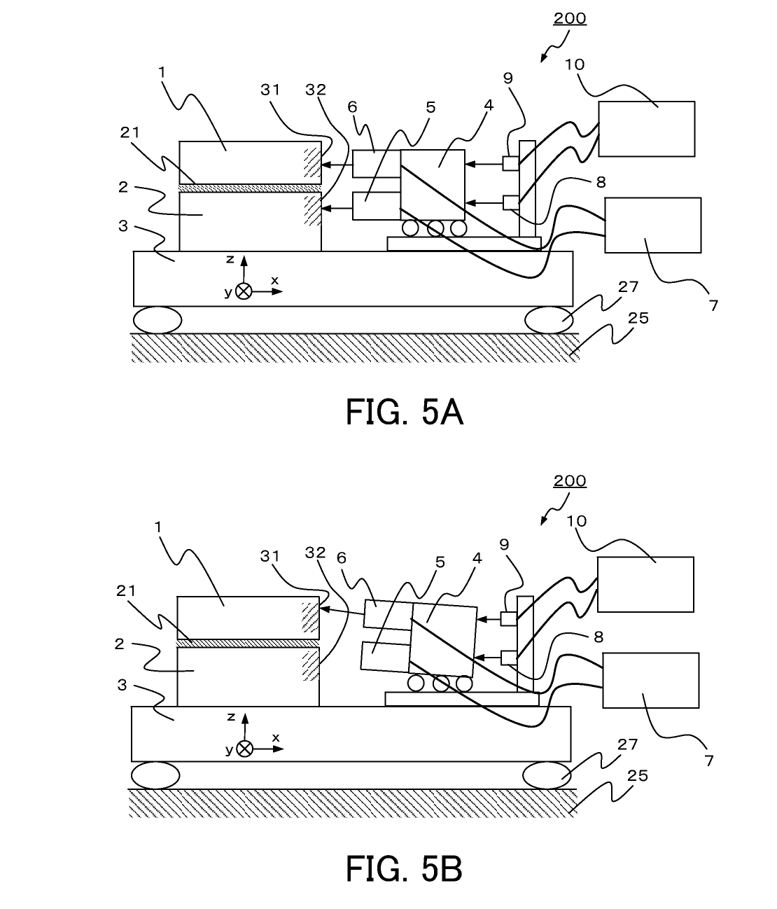

Next, a displacement measuring apparatus in Embodiment 2 of the present invention will be described. FIGS. 5A and 5B are schematic configuration diagrams of the displacement measuring apparatus in the present embodiment. FIG. 5A shows a case where a stage driving direction and a ranging direction of a ranging sensor are coincident with each other, and FIG. 5B shows a case where the stage driving direction and the ranging direction of the ranging sensor have a certain angle displacement. In FIGS. 5A and 5B, the descriptions of the same elements as those in Embodiment 1 will be omitted.

Reference numerals 8 and 9 denote non-contact type ranging sensors (a third detector) which are set on a fixed portion of the stage 4. The ranging sensors 8 and 9 can detect moving amounts of the ranging sensors 5 and 6, respectively. Reference numeral 10 denotes a controller (a measuring portion) of the ranging sensors 8 and 9. The controller 10 has a display function of output values of the ranging sensors 8 and 9.

A displacement measuring apparatus 200 of the present embodiment detects an angle displacement between a driving direction of the stage 4 (a stage driving direction) and a ranging direction of the ranging sensors 5 and 6 to correct displacement measurement information of the object to be measured 1 caused by the angle displacement. In other words, the ranging sensors 8 and 9 respectively measure moving amounts of the ranging sensors 5 and 6 to correct the displacement measurement information of the object to be measured 1 in driving the stage 4 by a driver (not shown). The correction is previously performed by the controller 10 before measuring the object to be measured 1 or is performed by the controller 10 at the time of measuring the displacement.

For example, a relative displacement δ′ of the object to be measured 1 is represented by the following expression (2), where displacements of the ranging sensors 8 and 9 are respectively defined as γ8 and γ9 when the stage 4 is driven by an arbitrary amount.

δ′={β0−α0(1−(γ9−γ8)/γ8)}−{β1−α1(1−(γ9−γ8)/γ8)} (2)

Thus, the displacement measuring apparatus 200 includes the ranging sensors 8 and 9 which detect the angle displacement between the ranging direction of the ranging sensors 5 and 6 and the moving direction of the stage 4. Therefore, according to the displacement measuring apparatus 200, the influence of the angle displacement in the stage driving direction and the ranging direction of the ranging sensors 5 and 6 is suppressed, and a highly accurate measurement can be performed.

### Embodiment 3

Next, a displacement measuring apparatus in

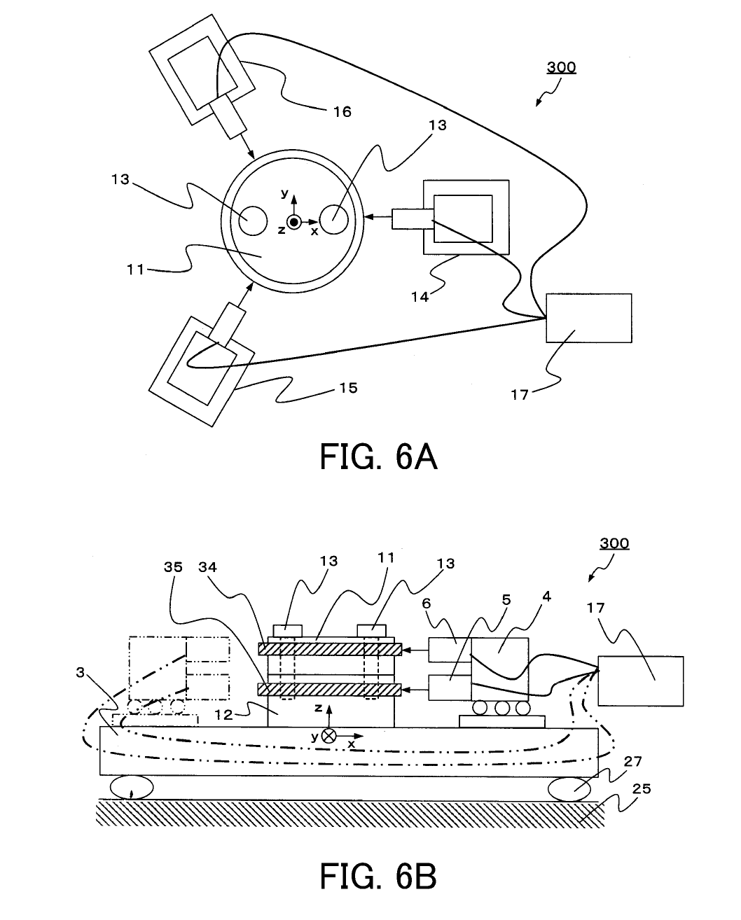

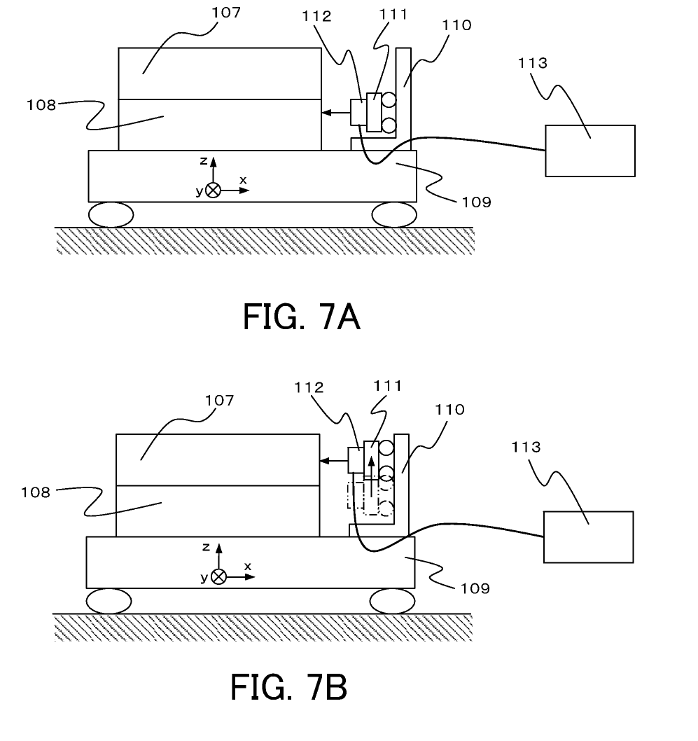

Embodiment 3 of the present invention will be described. FIGS. 6A and 6B are schematic configuration diagrams of a displacement measuring apparatus 300 in the present embodiment. FIG. 6A is a top view of the displacement measuring apparatus 300, and FIG. 6B is a side view of the displacement measuring apparatus 300. The displacement measuring apparatus 300 is a multiaxis displacement measuring apparatus which measures a displacement of the object to be measured in a plurality of directions.

In FIGS. 6A and 6B, reference numeral 11 denotes an object to be measured. In the displacement measuring apparatus 300 of the present embodiment, mirror finishing is performed for a part of an outer circumference of a circular cylindrical shape (a measurement point 34) by a precision lathe process or the like. Reference numeral 12 denotes a base that is a position reference. Similarly to the object to be measured 11, mirror finishing is performed for a part of an outer circumference of a circular cylindrical shape (a measurement point 35) by a lathe process or the like. The object to be measured 11 is fastened on the base 12 by a screw 13.

The displacement measuring apparatus 300 of the present embodiment, for example monitors a relative displacement when the object to be measured 11 and the base 12 receive thermal shock or vibration. Reference numerals 14 to denote displacement detecting apparatuses. The displacement detecting apparatuses 14 to 16 are, for example configured to include the stage 4 and the ranging sensors 5 and in the above embodiment. The displacement detecting apparatuses 14 to 16 are arranged around the object to be measured 11 at 120 degrees pitches one another.

A method of measuring the object to be measured 11 by the displacement detecting apparatuses 14 to 16 of the present embodiment will be omitted since it is the same as that of the above embodiment. As shown in FIGS. 6A and 6B, however, the displacement measuring apparatus 300 of the present embodiment measures the displacement of the object to be measured 11 in a plurality of different directions using the displacement detecting apparatuses 14 to 16. The plurality of displacement detecting apparatuses 14 to 16 are arranged around the object to be measured 11 which has a circular cylindrical shape to simultaneously measure the displacements of the object to be measured 11 to be able to obtain displacement information of the object to be measured 11 in an XY plane. In the present embodiment, the measurement of a relative displacement between the object to be measured and the base as a reference member with the passage of time or when an external force is applied has been described. The present embodiment is not limited to this, but for example it can also be used as a measuring apparatus when positioning the object to be measured with respect to the base with high accuracy.

The displacement measuring apparatus 300 of the present embodiment includes three displacement detecting apparatuses 14 to 16. The present embodiment is not limited to this, but may include two or four or more displacement detecting apparatuses. In these cases, the plurality of displacement detecting apparatuses are preferably arranged around the object to be measured at the similar pitches one another.

As described above, according to the displacement measuring apparatus of each of the above embodiments, in a precision industrial product, positioning with respect to a reference member that is a position reference or measurement of a minute position displacement of parts fixed on the reference member caused by disturbance such as vibration, shock, or thermal shock can be stably performed with higher accuracy. Therefore, according to each of the above embodiments, highly accurate displacement measuring apparatus and displacement measuring method can be provided. The displacement measuring apparatus does not have to be always equipped with the object to be measured. Therefore, even when there is no space where the ranging sensor is attached to the reference member, highly accurate measurement of a relative displacement can be performed. The displacement measuring apparatus of each of the above embodiments can be widely applied to a precision apparatus such as a stage apparatus, an optical apparatus, an exposure apparatus, or a system including these apparatuses.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-009538, filed on Jan. 20, 2009, which is hereby incorporated by reference herein in its entirety.

What is claimed is:

1. A displacement measuring apparatus which measures a displacement of an object to be measured, the displacement measuring apparatus comprising:
a first detector configured to detect a first origin position based on a distance to a reference member;
a second detector configured to detect a second origin position based on a distance to the object to be measured;
a moving portion mounting the first and second detectors and configured to move in a ranging direction of the first and second detectors; and
a measuring portion configured to measure a displacement of the object to be measured with respect to the reference member using the first and second origin positions detected while moving the first and second detectors.

2. A displacement measuring apparatus according to claim 1,
wherein the measuring portion measures the displacement of the object to be measured with respect to the reference member based on a displacement of a difference between an output value of the second detector when the first detector detects the first origin position and an output value of the second detector when the second detector detects the second origin position.

3. A displacement measuring apparatus according to claim 1, further comprising a third detector configured to detect an angle displacement between the ranging direction of the first and second detectors and the moving direction of the moving portion.

4. A displacement measuring apparatus which measures a displacement of an object to be measured in a plurality of directions, the displacement measuring apparatus comprising:
a plurality of displacement detecting apparatuses arranged around the object to be measured; and
a measuring portion configured to measure the displacement of the object to be measured with respect to a reference member based on an output of the plurality of displacement detecting apparatuses,
wherein each of the plurality of displacement detecting apparatuses comprises:
a first detector configured to detect a first origin position based on a distance to the reference member;
a second detector configured to detect a second origin position based on a distance to the object to be measured; and
a moving portion mounting the first and second detectors and configured to move in a ranging direction of the first and second detectors, and
wherein the measuring portion is configured to measure a displacement of the object to be measured with respect to the reference member using the first and second origin positions detected while moving the first and second detectors.

5. A displacement measuring method of measuring a displacement of an object to be measured, the displacement measuring method comprising the steps of :
moving a first detector in a ranging direction of the first detector;
detecting a first origin position by the first detector based on a distance to a reference member;
moving a second detector in a ranging direction of the second detector;
detecting a second origin position by the second detector based on a distance to the object to be measured; and
measuring a displacement of the object to be measured with respect to the reference member based on a displacement of a difference between an output value of the second detector when the first detector detects the first origin position and an output value of the second detector when the second detector detects the second origin position.
